(19) United States
(12) Patent Application Publication
(10) Pub. No.: US 2013/0044447 A1
(43) Pub. Date: Feb. 21, 2013

(54) VEHICLE-MOUNTABLE JUNCTION BOX, AND CIRCUIT MEMBER AND CIRCUIT UNIT USABLE FOR THE VEHICLE-MOUNTABLE JUNCTION BOX

(71) Applicants: Hirotomo Shiozaki, Shiga (JP); Ryusuke Kakoi, Shiga (JP); Toshitaka Kobayashi, Shiga (JP); Kengo Kimura, Shiga (JP); Shin Hasegawa, Shiga (JP)

(72) Inventors: Hirotomo Shiozaki, Shiga (JP); Ryusuke Kakoi, Shiga (JP); Toshitaka Kobayashi, Shiga (JP); Kengo Kimura, Shiga (JP); Shin Hasegawa, Shiga (JP)

(73) Assignees: FURUKAWA ELECTRIC CO., LTD., Tokyo (JP); FURUKAWA AUTOMOTIVE SYSTEMS INC., Shiga (JP)

(21) Appl. No.: 13/589,668

(22) Filed: Aug. 20, 2012

Related U.S. Application Data
(63) Continuation of application No. PCT/JP2011/053520, filed on Feb. 18, 2011.

(30) Foreign Application Priority Data
Feb. 19, 2010 (JP) 2010-034353

(51) Int. Cl. H05K 7/02; H05K 5/02; H05K 1/11

(52) U.S. Cl. 361/752; 361/760; 174/266

(57) ABSTRACT

A circuit member for a vehicle-mountable junction box is accommodated in the vehicle-mountable junction box. The circuit member is a metal core board including a metal core plate as a core. The core plate includes a separated part which is separated from a main part by a separating groove filled with an insulating material. Electronic components are mounted on both of a part including the main part and a part including the separated part.

### TECHNICAL FIELD

The present invention relates to a vehicle-mountable junction box, and more specifically to a vehicle-mountable junction box which can be improved in durability, and a circuit member and a circuit unit usable for the vehicle-mountable junction box.

### BACKGROUND ART

Vehicle-mountable junction boxes are available in a busbar system including internal wires in the form of a busbar wiring body, a printed circuit board system including internal wires in the form of a printed circuit board, and a combination thereof.

A vehicle-mountable junction box of the busbar wiring system has the following advantages. When the thickness of a copper alloy plate member used for a circuit pattern is increased, the pattern width can be decreased. In addition, the vehicle-mountable junction box of the busbar wiring system is suitable for mass production because the copper alloy plate is produced by press work.

A vehicle-mountable junction box of the printed circuit board system has the following advantages over a vehicle-mountable junction box of the busbar system. The design of the pattern circuit can be changed in accordance with the type, grade and shipping destination of the vehicle more easily, and the circuit pattern can be formed in a shorter time.

As described above, the circuit member as the busbar wiring body and the circuit member as the printed circuit board both have advantages, but there is a concern that the recent tendency of increasing the density of circuit members may raise the temperature thereof. In addition, automobiles are desired to have more functions and a certain size of space of compartment. For this reason, a junction box is occasionally mounted in a high-temperature engine room. Therefore, measures for preventing a temperature rise have become increasingly important in order to make the junction box durable.

Under these circumstances, when, for example, the printed circuit board is used as a circuit member, a metal core board is used in order to obtain a heat radiation effect.

However, a circuit member having a passive structure of causing the heat to escape does not prevent the temperature rise with certainty. Therefore, currently, high-cost electronic components and the like having a high heat-resistant temperature need to be used to prevent a temperature rise with certainty and thus to provide reliability.

When the procedure for assembling the vehicle-mountable junction box is complicated, the number of assembly steps, the number of components and the cost are increased, and also the vehicle-mountable junction box is liable to be influenced by the temperature due to a production error or the like and thus the durability of the vehicle-mountable junction box may be decreased.

Conventionally, as disclosed in Patent Document 1 specified below, a technology of dividing a metal core into a plurality of metal bodies in order to improve the reliability of the electronic components on a metal core board against heat is known. However, this technology is not for a circuit member for a vehicle-mountable junction box. Such a structure of dividing the core has not been adopted for a circuit member accommodated in a vehicle-mountable junction box.

According to one type of busbar wiring body, as disclosed in Patent Document 2 specified below, one plate including busbars connected to each other by a plurality of bridges so as not to be disassembled when being punched by press work is divided into a plurality of pieces, and then the resultant plurality of pieces are TOX-connected to be integral. This is done for improving the yield (number of acceptable products) and thus reducing the cost. The integrated busbars are fixed to an insulating plate.

However, in order to TOX-connect these separate busbars, a positioning jig is separately needed.

In addition, even the above-mentioned busbars are fixed to an insulating board, merely a planar structure can be obtained with no different layers being connected. In order to cause different layers to be connected to each other or to intersect each other so that the electronic components are not located at an excessively high density, an insulating plate needs to be divided into a plurality of pieces. In this case, the structure is complicated and the number of production steps is increased. In addition, a larger margin for molds is needed in order to produce a plurality of types of insulating plates.

A fuse holder which is to be mounted on a circuit member has a fuse terminal having a fuse connection part which is to be connected to a fuse. To the fuse connection part, a fuse housing having an opening into which a fuse can be inserted is attached. The fuse housing is a separate member (see Patent Document 3 below). Therefore, a structure for fixing the fuse housing is separately needed. In the case where, for example, the fuse housing is fixed on the circuit member, an extra stress may be applied to the circuit member when the fuse is attached or detached. When this stress applies a load on a soldered part, the durability is influenced. In addition, there is another inconvenience that the number of components is increased and thus the cost is raised.

There is an undesirable possibility that a structure for fixing the fuse holder has a similar inconvenience. This will be described in more detail. As disclosed in Patent Document 4 specified below, the fuse holder is directly fixed to a circuit member by a screw. Therefore, a stress generated when the fuse is inserted or drawn out can be received by a part for fixing the screw to the board and thus the stress can be suppressed from being applied to a soldered part of the fuse terminal.

However, the necessity of the screw increases the number of components and also the number of production steps. However, if the step of fixing by a screw is not performed and the fuse holder is fixed by, for example, only pressurizing, a stress is caused to the board and the reliability may be lost.

### CITATION LIST

### Patent Literature

Patent Document 1: Japanese Laid-Open Patent Publication No. Hei 8-288606
Patent Document 2: Japanese Laid-Open Patent Publication No. Hei 11-187542
Patent Document 3: Japanese Laid-Open Patent Publication No. 2007-311152
Patent Document 4: Japanese Laid-Open Patent Publication No. 2006-42586

### SUMMARY OF INVENTION

### Technical Problem

As described above, various measures have been taken conventionally to fulfill the high level of requirements on the durability, cost and the like, but no measures have been taken to solve the problems from a multifaceted point of view.

The present invention has a main object of improving the durability while, for example, reducing the cost and realizing a simple assembly structure.

### Solution to Problem

Means therefor is a circuit member for a vehicle-mountable junction box, which is to be accommodated in the vehicle-mountable junction box. The circuit member is a metal core board including a metal core plate as a core; the core plate includes a separated part which is separated from a main part by a separating groove filled with an insulating material; and electronic components are mounted on both of a part including the main part and a part including the separated part. In this case, it is preferable that the electronic components mounted on the part including the main part and the part including the electronic components mounted on the separated part are distinguished from each other based on a heat-resistant temperature or a heat-generating temperature of the electronic components.

Another means is a circuit member for a vehicle-mountable junction box, which is to be accommodated in the vehicle-mountable junction box. The circuit member is a busbar wiring body including busbars; the busbar wiring body includes an insulating plate and the busbars for holding the insulating plate from a front surface and a rear surface of the insulating plate; the insulating plate has a plurality of positioning parts for positioning the busbars; and the busbars include the plurality of busbars positioned by the positioning parts.

Still another means is a circuit unit for a vehicle-mountable junction box, which is to be accommodated in the vehicle-mountable junction box. Circuit members included in the circuit unit are a metal core board including a metal core plate as a core and a busbar wiring body including busbars; the core plate of the metal core board includes a separated part which is separated from a main part by a separating groove filled with an insulating material; the metal core board has a connection hole formed therein which is electrically connected to the core plate; and the connection hole is connected to busbars of the busbar wiring body. In this case, as the busbar wiring body, a circuit member formed of the busbar wiring body described above is preferably usable.

Still another means is a circuit unit for a vehicle-mountable junction box, which is to be accommodated in the vehicle-mountable junction box. A connector holder is fixed on a circuit member included in the circuit unit; a top surface of the connector holder has an engaging hole formed therein; a fuse holder having a bottom surface having an engaging protrusion, which is to be inserted into, and engaged with, the engaging hole; and the fuse holder is fixed on the connector holder by mutual engagement of the engaging hole and the engaging protrusion. In this case, as the circuit member, the metal core board or the busbar wiring body described above is preferably usable.

Still another means is a vehicle-mountable junction box for accommodating the circuit member described above, in which a connection part of a connection terminal, to be connected to a fuse or a connector in a casing for accommodating the circuit member, has a housing for surrounding the connection part of the connection terminal, the housing being integrally formed with the connection part.

Still another means may be a vehicle-mountable junction box accommodating the circuit member described above.

### Advantageous Effects of Invention

The present invention provides a highly reliable vehicle-mountable junction box which can reduce the cost of the material, production work and the like, and also can improve the durability by especially avoiding a temperature rise or inconveniences which have conventionally occurred at a high temperature.

### BRIEF DESCRIPTION OF DRAWINGS

FIG. 1 provides a plan view and a cross-sectional view of a circuit member.

FIG. 2 is an exploded isometric view of a vehicle-mountable junction box.

FIG. 3 shows production steps of the circuit member.

FIG. 4 is a plan view of a core plate.

FIG. 5 is an exploded isometric view of a circuit member.

FIG. 6 is an exploded isometric view of a part of the circuit member.

FIG. 7 shows a processed state of a part of the circuit member.

FIG. 8 is an exploded isometric view of a circuit unit.

FIG. 9 is a partially cross-sectioned side view showing an important part of the circuit unit.

FIG. 10 is an exploded isometric view of the vehicle-mountable junction box.

### DESCRIPTION OF EMBODIMENTS

Hereinafter, an embodiment of the present invention will be described with reference to the drawings.

According to the present invention, the object of improving the durability against use in a high-temperature environment while, for example, reducing the cost and realizing a simple assembly structure, is achieved by a circuit member 11 and a circuit unit 51 of a vehicle-mountable junction box as described below and a vehicle-mountable junction box 71 using the same.

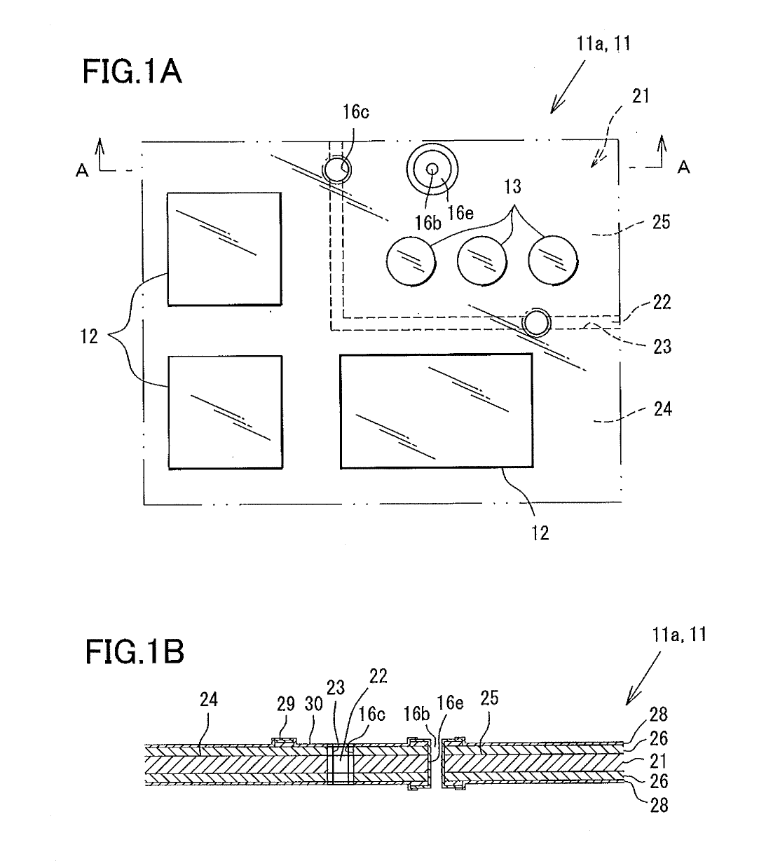

More specifically, as shown in FIG. 1, the circuit member 11 for the vehicle-mountable junction box is a metal core board 11a including a metal core plate 21 as a core. The core plate 21 has a separated part 25 which is separated from a main part 24 by separating grooves 23 filled with an insulating material 22. A part including the main part 24 and a part including the separated part 25 respectively have electronic components 12 and 13 mounted thereon.

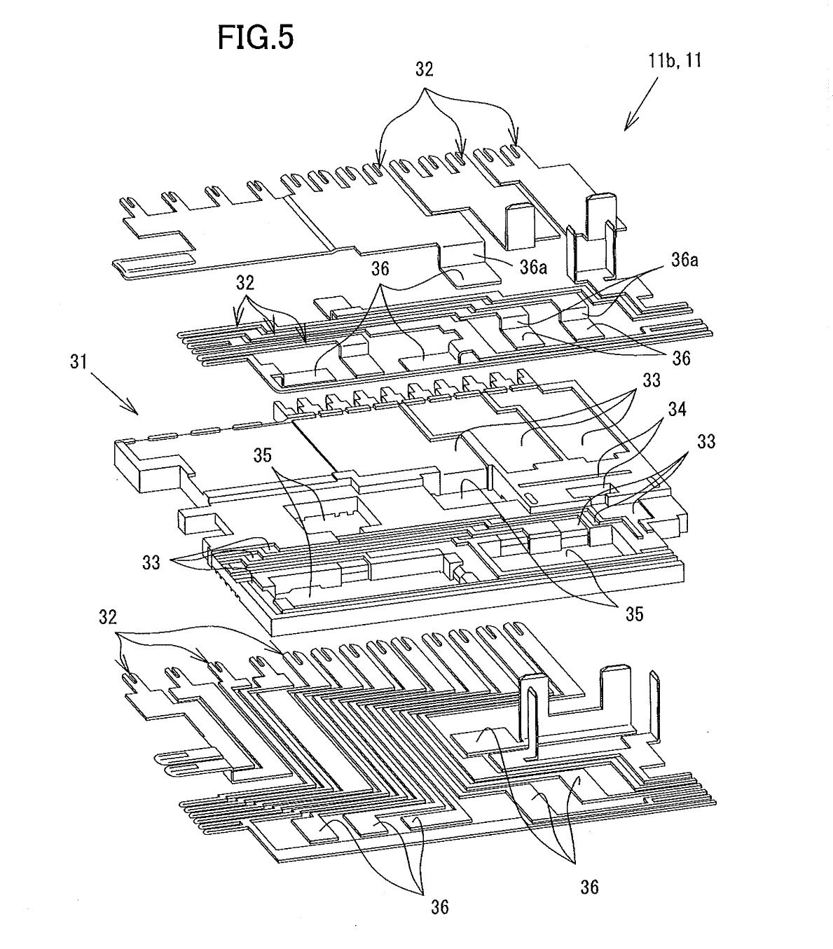

As shown in FIG. 5, another circuit member 11 for a vehicle-mountable junction box is a busbar wiring body 11b having busbars. The busbar wiring body 11b includes an insulating plate 31 and the busbars 32 for holding the insulating plate 31 from a front surface and a rear surface of the insulating plate 31. The insulating plate 31 has a plurality of recessed parts 33 for positioning the busbars 32. The busbars 32 include a plurality of busbars 32 positioned by the recessed parts 33.

A circuit unit 51 for the vehicle-mountable junction box includes at least one of the metal core board 11a and the busbar wiring body 11b.

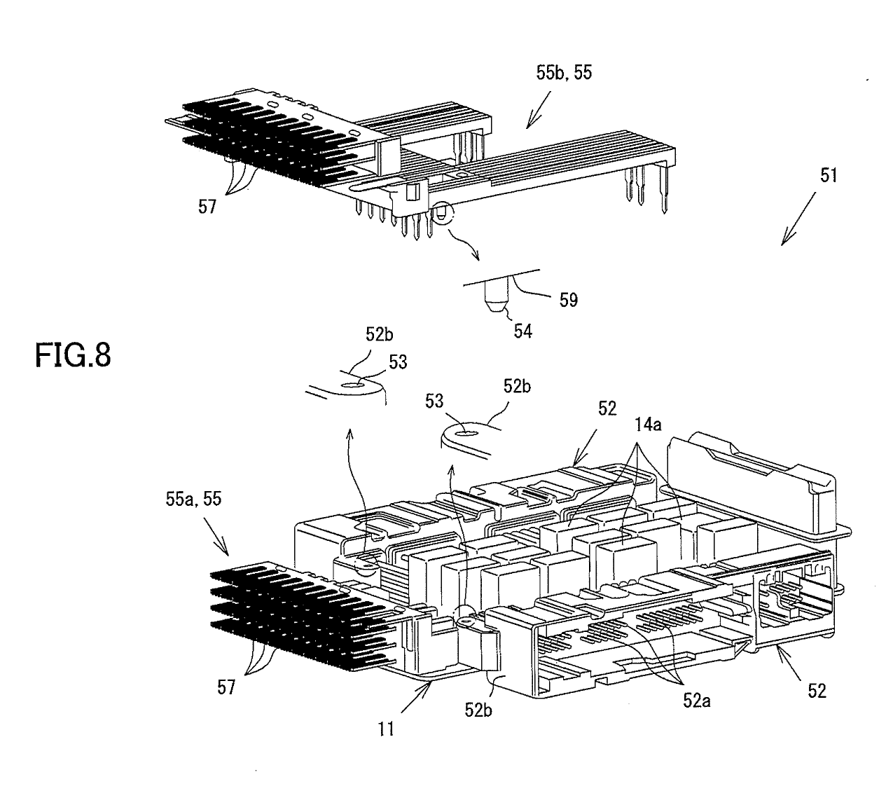

Preferably, as shown in FIG. 8, the circuit unit 51 has a structure shown in FIG. 8. A connector holder 52 is fixed on the circuit member 11, and a top surface of the connector holder 52 has an engaging hole 53 formed therein. A fuse holder 55 having a bottom surface having an engaging protrusion 54, which is to be inserted into, and engaged with, the engaging hole 53, is provided. Owing to the mutual engagement of the engaging hole 53 and the engaging protrusion 54, the fuse holder 55 is fixed on the connector holder 52.

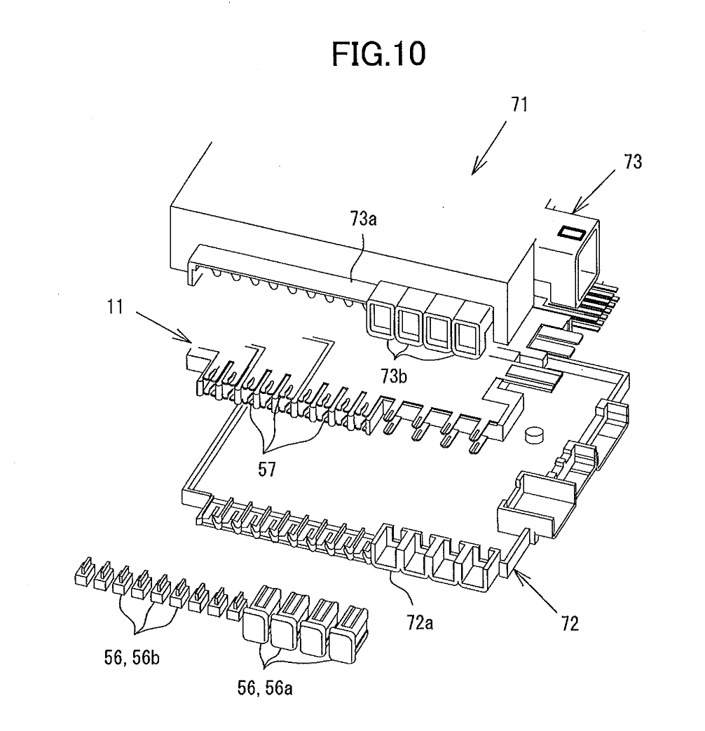

The vehicle-mountable junction box 71 accommodates the circuit member 11 and/or the circuit unit 51. Preferably, the vehicle-mountable junction box 71 has a structure shown in FIG. 10. A lower case 72 and an upper case 73 form a casing for accommodating the circuit member 11. In the casing, fuses 56 are connected to fuse terminals 57. Fuse connection parts of the fuse terminals 57 which are connected to the fuses 56 respectively have housing parts 72a and housing parts 73a. The housing parts 72a and the housing parts 73a surround, and are integrated with, the connection parts.

First, the circuit member 11 will be described, and then the circuit unit 51 and the vehicle-mountable junction box 71 will be described.

FIG. 1A is a plan view showing a part of the metal core board 11 as the circuit member 11, and FIG. 1B is a cross-sectional view thereof taken along line A-A in FIG. 1A. In FIG. 1A, the circuit pattern is omitted for the sake of convenience.

In the present invention, the “metal core board 11a” means a board including the metal core plate 21 as an intermediate layer such as, for example, an insulating board (laminate) before a wiring pattern is formed thereon, a metal core printed wiring board having a wiring pattern formed on a laminate, a metal core printed circuit board having electronic components mounted on a metal core printed wiring board, or the like.

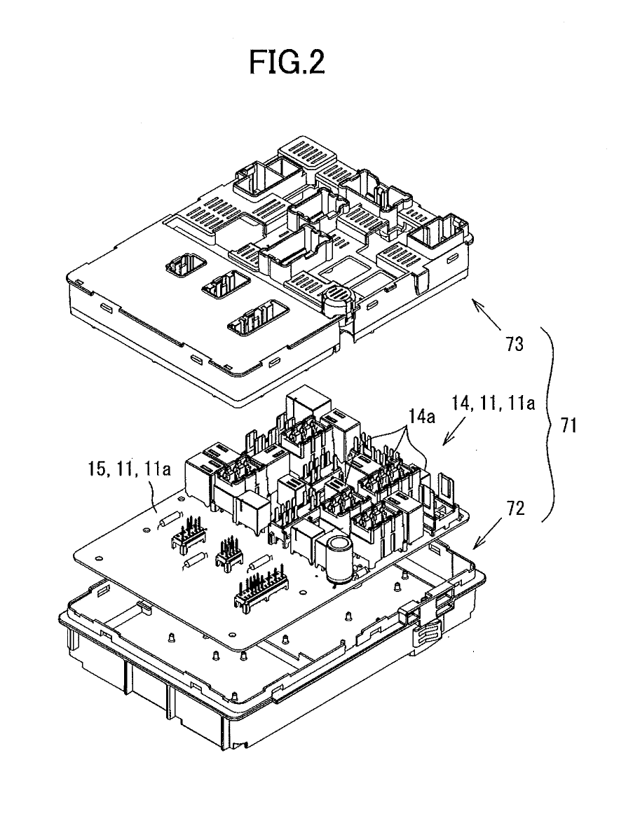

The metal core board 11a is to be accommodated in, for example, the vehicle-mountable junction box 71 as shown in FIG. 2 as an example. As shown in FIG. 1, the core plate 21 acting as a core which forms the intermediate layer of the metal core board 11a is separated into the main part 24 and the separated part 25 by the separating grooves 23 as described above. Any number of separated parts 25 may be set in accordance with a desired circuit, and such separated parts 25 may have any shape. On both of two surfaces of the core plate 21, an insulating layer 26 is formed. The separated grooves 23 between the main part 24 and the separated part 25 are filled with the insulating material 22, which is also used for forming the insulating layer 26.

Owing to such a structure, the main part 24 and the separated part 25 are located on the same plane but are electrically independent from each other by the insulating layer 26.

In FIG. 2, reference sign 14 represents a part of a metal core board on which electronic components 14a are mounted (this part is referred to as the “metal core printed circuit board”), and reference sign 15 represents a part of the metal core board on which the electronic components 14a are not mounted (this part is referred to as the “metal core printed wiring board”). Reference sign 72 represents the lower case, and reference sign 73 represents the upper case.

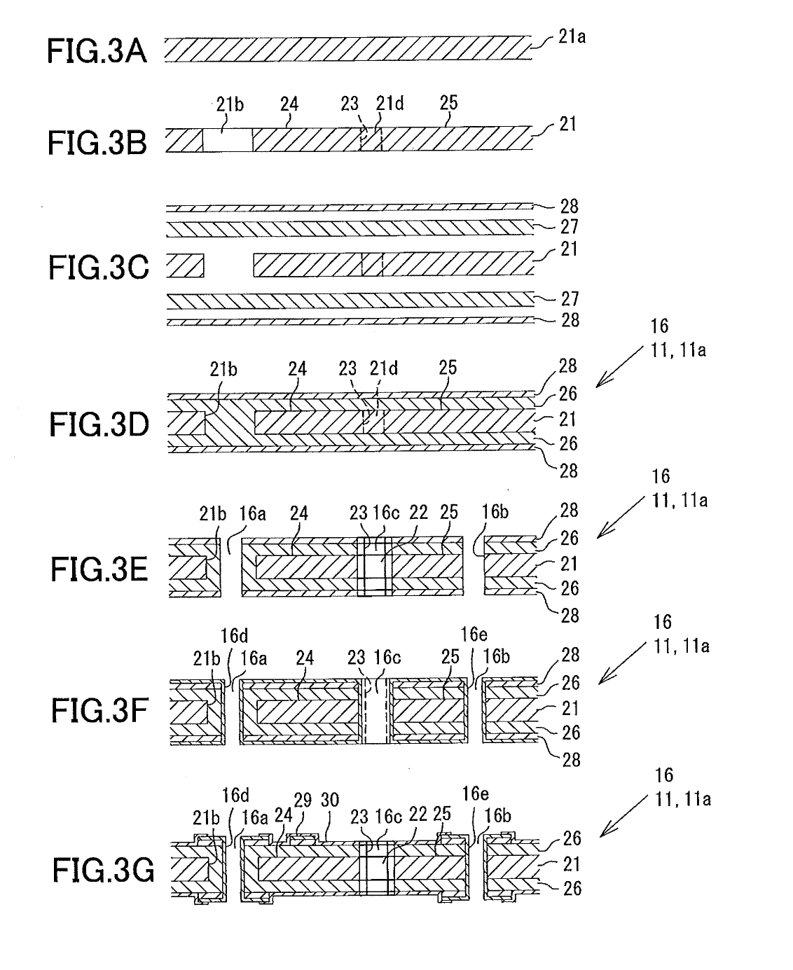

The part of the metal core board 11 acting as the metal core printed wiring board 15 is produced by the steps shown in FIG. 3.

The production steps will be described. First, a metal plate having a prescribed thickness (for example, copper plate, aluminum plate) to be used as the core plate 21 is cut to obtain a material plate 21a (see FIG. 3A).

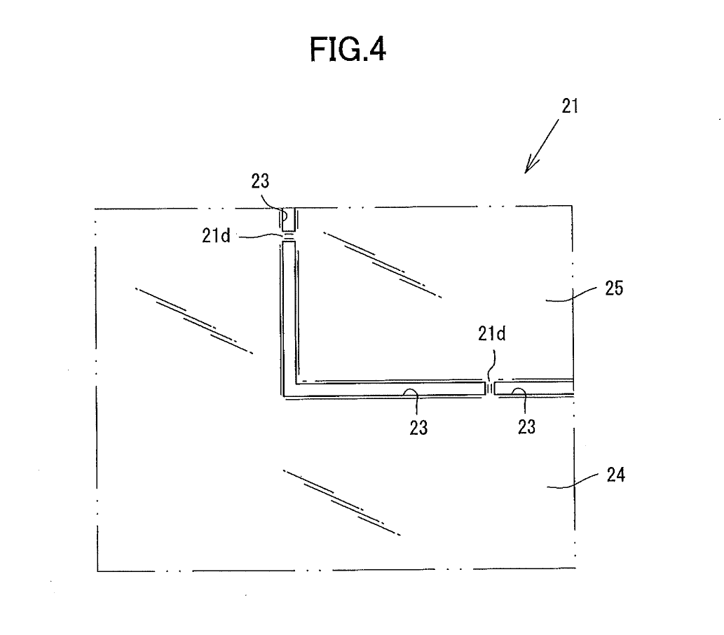

Then, at prescribed positions of the material plate 21a, desired bores 21b and the separating grooves 23 are made to form the core plate 21 (see FIG. 3B). FIG. 4 is a plan view showing an example of the core plate 21. The core plate 21 includes the separated part 25 surrounded by the plurality of separating grooves 23 and separating connection parts 21d located between the separating grooves 23.

Next, the two surfaces of the core plate 21 are roughened in order to improve the adhesiveness of a resin.

Then, on each of the two roughened surfaces of the core plate 21, a prepreg 27 and a copper foil 28 are stacked sequentially (see FIG. 3C). The resultant core plate 21 is sandwiched between stainless steel plates (not shown) and heat-pressed to obtain an integral laminate (see FIG. 3D). During the integration step, the bores 21b and the separating grooves 23 are filled with the resin of the prepreg 27. The resin filling the separating grooves 23 acts as the insulating material 22.

As a result of the formation of the integral laminate, the copper foil 28 is present on each of the two surfaces of the core plate 21, with the insulating layer 26 formed of the prepreg 27 being interposed between the copper foil 28 and the core plate 21. The integral laminate is a copper-clad laminate 16.

Next, at prescribed positions at which through-holes are to be formed, through-bores 16a and 16b are formed, and at the positions of the separating connection parts 21d between the separating grooves 23, through-bores 16c are formed (see FIG. 3E). By the through-bores 16c formed at the positions of the separating connection parts 21d, the separated part 25 of the core plate 21 is separated from a surrounding area and becomes electrically independent. Thus, the metal core board 11a in which the core plate 21 is divided is obtained. The formation of the through-bores 16c for making the separated part independent may be performed at any stage after the insulating layer 26 is formed.

Next, the through-bores 16a and 16b for forming the through-holes are subjected to necessary processing such as desmearing or the like and then plated. Conductive parts are formed on an inner circumferential wall of each of the through-bores 16a and 16b and the vicinity thereof (see FIG. 3F). The through-bores 16a are plated with a well-known through-bore plating material 16d, and the through-bore plating material 16d and the core plate 21 are not in contact with each other. A plating layer 16e provided on the inner circumferential wall of each of the through-bores 16b is electrically in contact with the core plate 21. The plating layer 16e is a conductive part which defines a connection hole for using the core plate 21 as a part of a circuit. The plating layer 16e is formed when necessary, and a terminal (not shown) is inserted into each of the through-bores 16b and connected therewith by soldering.

Then, necessary processing such as formation of a circuit pattern 29, formation of a solder resist 30 and the like is performed. As a result, the part of the metal core board 11a acting as the metal core printed wiring board 15 is obtained (see FIG. 3G).

Now, a structure of the core plate 21 for producing the metal core board 11a as described above will be described. The core plate 21 is structured so as to provide a heat radiation effect, to be reduced in size, to be improved in mounting efficiency, and to positively protect the electronic components against heat.

In the core plate 21 shown in FIG. 4 as an example, the entirety of the separated part 25 is not shown for the sake of convenience. The core plate 21 includes the plurality of separating grooves 23 made intermittently so as to form a closed loop shape. By the formation of the separating grooves 23, the separating connection parts 21d and the separated part 25 are formed.

The separating grooves 23 are structured to control heat transmission from an adjacent part (the main part 24 or the separated part 25) so that the electronic components 12 and 13 are positively protected against heat. More specifically, the separating groove 23 have a width which is sufficient to block or suppress heat transmission. This width is appropriately set based on the heat-resistant temperature or the heat-generating temperature of the electronic components 12 and 13. For example, it is preferable that the electronic components 13 which are low-temperature-resistant such as an aluminum electrolytic capacitor and the like are mounted on the separated part 25, and that the electronic components 12 of a heat-generating type such as a CPU and the like are mounted on the main part 24.

In addition to the width of the separating grooves 23, the form and the location of the separated part 25 defined by the separating grooves 23 are also appropriately set based on the heat-resistant temperature or the heat-generating temperature of the electronic components 12 and 13.

In this manner, the low-temperature-resistant electronic components 13 can be positively protected against heat generated by the heat-generating electronic components 12. Namely, the prescribed electronic components are prevented from being raised in temperature, or the entirety of the circuit member 11 is prevented from being raised in temperature. As a result, relatively low-cost low-temperature-resistant electronic components 13 can be used. Thus, the cost can be reduced and the durability can be improved.

Since a plurality of circuits can be formed on one metal core board 11a, the number of components is decreased as compared with the case where a plurality of metal core boards are connected to each other. Thus, the cost can be reduced and the mounting efficiency can be improved.

For designing the metal core board 11a, the low-temperature-resistant electronic components 13 are provided as being placed together, and the heat-generating electronic components 12 are provided as being placed together, so that the electronic components 13 and the electronic components 12 are distinguished from each other by core separation. When the electronic components 13 and the electronic components 12 are respectively provided as being placed together as much as possible, even when the width of the separating grooves 23 is enlarged in order to block the heat transmission, the size of the metal core board 11a can be reduced and the mounting efficiency can be improved.

FIG. 5 is an isometric view showing the busbar wiring body 11b as the circuit member 11 in a disassembled state. As shown in this figure, the busbar wiring body 11b includes one insulating plate 31 formed of a synthetic resin and the plurality of busbars 32 for holding the insulating plate 31 from the front surface and the rear surface of the insulating plate 31.

The insulating plate 31 is formed to have an appropriate shape in accordance with a desired circuit. The insulating plate 31 has the plurality of recessed parts 33 in the front and rear surfaces thereof. The recessed parts 33 are provided as positioning parts for fixing the plurality of busbars 32. The insulating plate 31 further has insertion holes 34 into which terminals of the busbars 32 are to be inserted, and also openings 35. The busbars 32 fixed on the front surface of the insulating plate 31 and the busbars 32 fixed on the rear surface of the insulating plate 31 are joined to each other via the openings 35 at an intermediate position in a thickness direction of the insulating plate 31.

The busbars 32 are formed by press-punching a copper alloy member or the like as is well known. When being fixed to the insulating plate 31, the busbars 32 as a whole have an appropriate shape in accordance with a desired circuit. However, before being fixed, the plurality of busbars 32 are separate as described above. In other words, the plurality of busbars 32 are like a busbar conventionally formed of one piece of member being divided into a plurality of pieces.

The plurality of busbars 32 are respectively formed to have a shape suitable to a position at which the respective busbar 32 is to be fixed in accordance with a desired circuit. Joining parts 36 are formed, in a part of the plurality of busbars 32, for joining the busbars 32 on the front surface of the insulating plate 31 and the busbars 32 on the rear surface of the insulating plate 31 to each other when the busbars 32 hold the insulating plate 31 from both surfaces of the insulating plate 31. The joining parts 36 are provided in order to realize connection of different layers. Leg parts 36a extending in the thickness direction of the insulating layer 31 are provided in either one of, or both of, the busbars 32 on the front surface and the busbars 32 on the rear surface. An assembly of each of the joining parts 36 and a corresponding leg part 36a has an L-shaped cross-section.

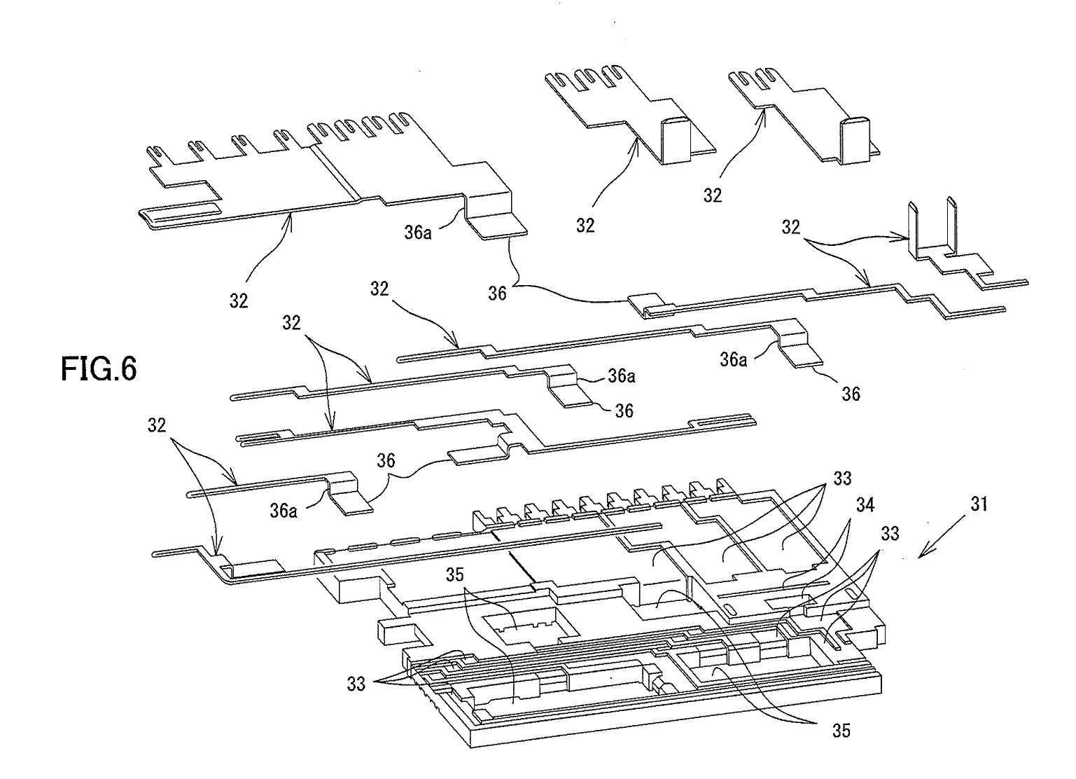

FIG. 6 is an exploded isometric view of the insulating plate 31 and the plurality of busbars 32 to be fixed to the front surface of the insulating plate 31. For assembly, the plurality of busbars 32 may be respectively fixed to the recessed parts 33 of the insulating plate 31. The busbars 32 may be fixed to the insulating plate 31 by an appropriate well-known technique. For example, weldable protrusions (not shown) protruding toward the insulating plate 31 are formed on surfaces of the busbars 32. After the busbars 32 are placed on the insulating plate 31, the weldable protrusions are welded such that heads thereof are pressed to be expanded.

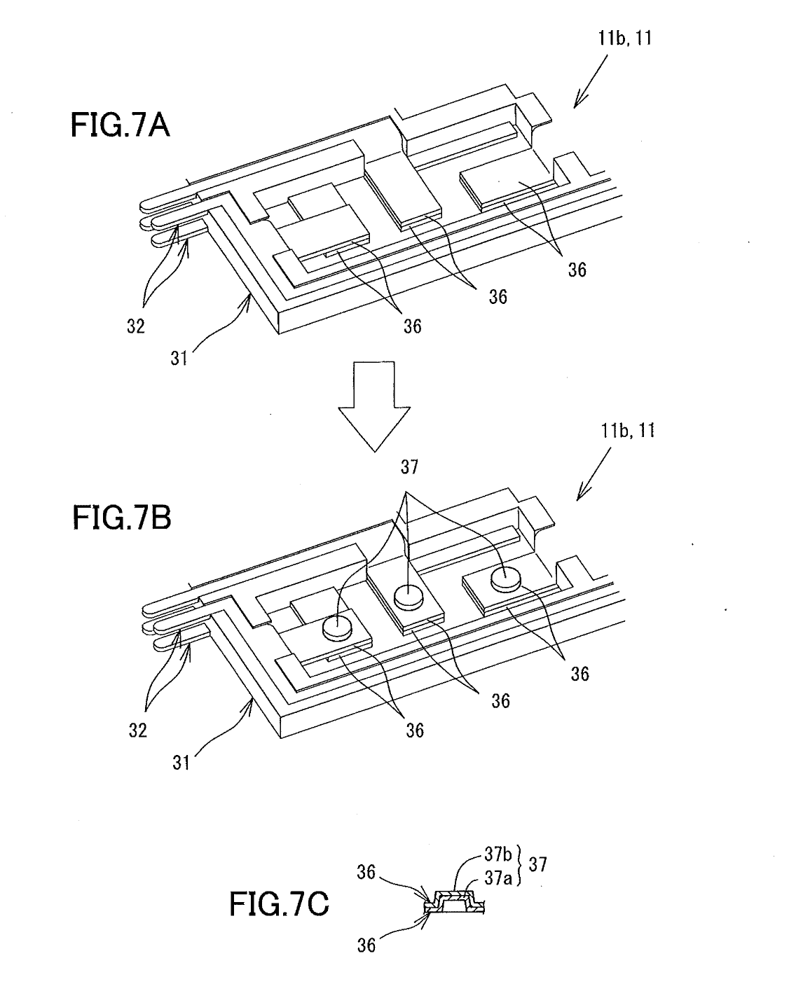

When the plurality of busbars 32 are fixed to the insulating plate 31, the state shown in FIG. 7 is obtained. In this state, the joining parts 36 of the busbars 32 are mutually joined together. In order to keep the connection, as shown in FIG. 7B, TOX-connected parts 37 are formed on the joining parts 36. The TOX-connected parts 37 are each provided as a connection structure for connecting and thus integrating the joining parts. The connection structure may be formed by, for example, welding or the like.

TOX connection is a technique of connecting a plurality of metal plates. As shown in a cross-sectional view of FIG. 7C, the plurality of metal plates are mechanically integrated together such that an outer surface of a recessed part 37a formed in one of the metal plates (joining part 36) is press-fit into an inner surface of a recessed part 37b formed in the other metal plate (joining part 36). TOX connection has advantages that, for example, material chips are not generated as a result of the processing and that the processing is easy.

The busbar wiring body 11b having such a structure can improve the production yield of the busbars 32 and thus can suppress the cost for the material. In addition, the insulating plate 31 has the recessed parts 33 for positioning the busbars 32. Therefore, no positioning jig is necessary for the TOX connection, unlike the case where the TOX connection is made before the busbars 32 are fixed to the insulating plate 31. In a sense, the insulating plate 31 also acts as the positioning jig. Therefore, the cost for the processing can be reduced.

TOX connection performed by use of a jig after correct positioning does not have a high operability and thus defects such as TOX position shift or the like may occur. However, in this embodiment, the positions of the busbars 32 are regulated by the insulating plate 31 as described above. Therefore, the processing is made easy and is performed in the state where all the busbars 32 are connected at a correct positional relationship. Thus, there is no undesirable possibility of connection defect. There is no undesirable possibility either that, for example, when the busbars 32 are fixed to the insulating plate 31, the busbars 32 or the TOX-connected parts thereof are distorted. For this reason, the connected parts or the like are not adversely influenced by thermal expansion. Namely, unexpected damages due to a high temperature can be avoided and the durability can be improved.

In addition, since the busbars 32 include the joining parts 36, connection and intersection of the different layers are realized by one insulating plate 31. Therefore, the busbar wiring body 11b has a simpler structure than in the case where the insulating plate 31 is divided into a plurality of pieces. The number of the steps of assembly and the cost for producing the insulating plate 31 are decreased, resulting in low-cost production.

Now, the circuit unit 51 will be described.

The circuit unit 51 includes the metal core board 11a or the busbar wiring body 11b as the circuit member 11, as well as the electronic components 12, 13 and 14a, the connector holder 52, the fuse holder 55 and the like mounted on the metal core board 11a or the busbar wiring body 11b.

In the case where the metal core board 11a and the busbar wiring board 11b are used as the circuit members 11, it is preferable that the busbars 32 of the busbar wiring body 11b are directly or indirectly connected to the through-bores 16b (see FIG. 1 and FIG. 3G) as the connection holes formed in the metal core board 11a for using the core plate 21 as a part of the circuit, although this structure is not specifically shown in the figure. Since the circuit members 11 are connected to each other easily with no use of a separate connector, the number of the components and the cost can be decreased.

The connector holder 52 and the fuse holder 55, and the mounting thereof will be described. The connector holder 52 is provided for, for example, detachably connecting a connector (not shown) for electrically connecting a wire harness (not shown). As shown in FIG. 8, the connector holder 52 includes connector terminals 52a, and a housing 52b formed of an insulating resin is provided around the connector terminals 52a.

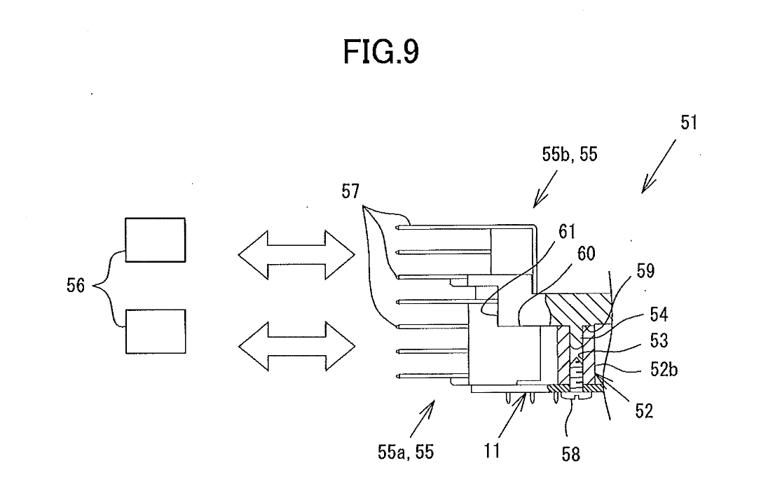

As shown in FIG. 9, a part of the housing 52b of the connector holder 52 is fixed to the circuit member 11 by a screw 58. In this example, as shown in FIG. 8, two connector holders 52 are located parallel to each other while having an interval therebetween.

The fuse holder 55 includes the fuse terminals 57 to be connected to the fuses 56. In the example shown in the figure, two fuse holders 55, namely, a first fuse holder 55a and a second fuse holder 55b, are mounted on the circuit member 11 as being stacked vertically.

The lower, i.e., first fuse holder 55a which is mounted on the circuit member 11 is fixed to the circuit member 11 by a screw in substantially the same manner as the conventional manner. The first fuse holder 55a is fixed at such a position that the first fuse holder 55a bridges over ends of the two connector holders 52.

The upper, i.e., second fuse holder 55b stacked on the first fuse holder 55a is pressurized into, and thus fixed to, the connector holders 52 in order to decrease the number of components and the number of assembly steps.

Specifically, the housings 52b of the two connector holders 52 fixed to the circuit member 11 by the screws 58 each have the engaging hole 53 extending in the thickness direction formed therein. As shown in FIG. 9, the engaging hole 53 runs through the housing 52b in the thickness direction so as to be usable for fixing the connector holder 52 by the screw 58. The engaging hole 53 may be formed in only a top part of the housing 52b, as is necessary to fix the second fuse holder 55b.

The second fuse holder 55b includes an overlapping part 59 bridging over the two connector holders 52 and overlapping the engaging hole 53. The engaging protrusion 54 to be inserted into the engaging hole 53 is formed on a bottom surface of the overlapping part 59 integrally with the overlapping part 59. The engaging protrusion 54 is cylindrical in the figure but may be of any other shape.

The first fuse holder 55a and the second fuse holder 55b have the fuse terminals 57, and the fuse terminals 57 have engaging parts which are engageable with each other. The engaging parts are formed on the side of the fuse connection parts. As shown in a cross-section of FIG. 9, the first fuse holder 55a has a concaved engaging part 60 having a shape as obtained by cutting an upper inner part of the circuit member 11 so as to have an L-shaped cross-section.

The second fuse holder 55b has a convexed engaging part 61 at a part facing the concaved engaging part 60. The convexed engaging part 61 has a protruding L-shaped cross-section.

In the circuit unit 51 having such a structure, the connector holders 52 and the first fuse holder 55a are fixed to the circuit member 11 by the screws, and then the second fuse holder 55b is fixed to the connector holders 52 by merely fitting the second fuse holder 55b from above. By this engagement, the convexed engaging part 61 of the second fuse holder 55b is engaged with the concaved engaging part 60 of the first fuse holder 55a. Thus, the convexed engaging part 61 receives a load applied on the first fuse holder 55a when the fuses 56 are inserted.

As described above, no screw is needed to fix the second fuse holder 55b. Therefore, the number of components is decreased and the assembly work is simplified, which can reduce the cost.

In addition, a stress applied when the fuses 56 are inserted into, or drawn out from, the second fuse holder 55b is received by the engaging protrusions 54. Therefore, a soldered part of each fuse terminal 57 of the second fuse holder 55b is prevented from being supplied with a load. Moreover, a stress applied when the fuses 56 are inserted into, or drawn out from, the first fuse holder 55a is received by the screws (not shown) used for the fixation and also by the engaging protrusions 54 of the second fuse holder 55b. Therefore, a soldered part of each fuse terminal 57 of the first fuse holder 55a is also prevented from being supplied with a load. Especially because the engaging holes 53 into which the engaging protrusions 54 are to be inserted are also used as the holes for fixing the connector holders 52 by the screws 58, the above-mentioned alleviating effect is highly significant. Thus, even if the circuit unit 51 is placed in an environment in which the temperature becomes high and low repeatedly, a desired function can be provided with certainty, and the reliability and the durability are improved.

In the example of FIG. 8 and FIG. 9, the metal core board 11a is used as the circuit member 11. The same is true with the case where the busbar wiring body 11b is used as the circuit member 11.

Finally, the vehicle-mountable junction box 71 will be described.

The vehicle-mountable junction box 71 includes the circuit unit 51, including the metal core board 11a or the busbar wiring body 11b as the circuit member 11, accommodated in a casing formed of, for example, the lower case 72 and the upper case 73. The form of the lower case 72 and the upper case 73 is appropriately set in accordance with a desired circuit.

In order to further decrease the number of components and thus to reduce the cost and also to improve the durability, the connection parts of the connection terminals, to be connected to the fuses 56 or the connectors (not shown) in the casing for accommodating the circuit member 11, have housing parts for surrounding connection parts. The housing parts are formed integrally with the connection parts.

FIG. 10 is an exploded isometric view showing an example of the vehicle-mountable junction box 71. In FIG. 10, a separate fuse housing is not shown.

As shown in this figure, the lower case 72 and the upper case 73 have the fuse terminals. At the connection parts of the fuse terminals 57 which are to be connected to the fuses, the first housing parts 72a and the second housing parts 73a protruding so as to cover the connection parts are formed integrally with the connection parts.

The first fuse housing parts 72a are formed on the lower case 72 and each have a shape generally like a gutter or a groove which is opened upward. A detailed shape thereof is appropriately set in accordance with the form of the connection parts or the like. In the example of FIG. 10, the housing parts 72a corresponding to the fuse connection terminals for a medium-level electrical current are formed to be gutter-shaped, and the housing parts 72a corresponding to the fuse connection terminals for a low-level electrical current are formed to be thin, groove-shaped. Such a shape difference is based on a size difference of the fuses 56 to be attached.

By contrast, the second housing parts 73a are formed on the upper case 73 and each have a shape which is opened downward. The first housing parts 72a and the second housing parts 73a, when being engaged with each other, form prescribed tube-like housings which surround fuses 56a for the medium-level electrical current or fuses 56b for the low-level electrical current. A detailed shape of the second housing parts 73a is also appropriately set in accordance with the form of the connection parts or the like. In the example of FIG. 10, the second housing parts 73a to be connected to the fuses 56a for the medium-level electrical current are longer than the corresponding first housing parts 72a, and each have a square frame part 73b. The frame part 73b acts as a tip part of the corresponding housing. Owing to the frame part 73b, the lower case 72 and the upper case 73 become more integral with each other.

The vehicle-mountable junction box 71 having such a structure does not need a separate fuse housing. Therefore, the number of components is decreased, and the load of the assembly work is alleviated. Thus, the cost can be reduced.

The load applied on the housing parts 72a and 73a when the fuses 56 are inserted or drawn out is received by the lower case 72 and the upper case 73. Therefore, the load is not transmitted to any other part, for example, a soldered part of the circuit member 11, unlike the case where the housing is formed of a separate member. Thus, any extra stress is not applied. Therefore, even if the vehicle-mountable junction box 71 is placed in an environment in which the temperature becomes high and low repeatedly, a desired function can be provided with certainty and the reliability and the durability are improved.

The busbar wiring body 11b is used as the circuit member 11 in the example of FIG. 10, but the same is true with the case where the metal core board 11a is used as the circuit member 11.

The circuit member 11, the circuit unit 51, and the vehicle-mountable junction box 71 as described above can reduce the cost of the material and the production work, and can especially avoid a temperature rise or inconveniences which have conventionally occurred at a high temperature. The resultant vehicle-mountable junction box 71 is highly durable.

The positioning part according to the present invention corresponds to the recessed part 33 in the embodiment; and in the same manner,

the connection structure corresponds to the TOX-connected part 37;

the connection hole corresponds to the through hole 16b;

the casing corresponds to the lower case 72 and the upper case 73;

the connection terminal corresponds to the fuse terminal 57; and

the housing corresponds to the housing parts 72a and 73a.

However, the present invention is not limited to the above-described embodiment, and can be carried out in many other embodiments.

For example, the positioning part may be provided by a protrusion engageable with the busbar or the like instead of the recessed part.

The housing integral with the casing may be formed at apart connected to the connector.

### REFERENCE SIGNS LIST

11 . . . Circuit member
11a . . . Metal core board
11b . . . Busbar wiring board
12, 13, 14a . . . Electronic component
16b . . . Through-hole
21 . . . Core plate
22 . . . Insulating material
23 . . . Separating groove
24 . . . Main part
25 . . . Separated part
31 . . . Insulating plate
32 . . . Busbar
33 . . . Recessed part
36 . . . Joining part
37 . . . TOX-connected part
51 . . . Circuit unit
52 . . . Connector holder
53 . . . Engaging hole
54 . . . Engaging protrusion
55 . . . Fuse holder
57 . . . Fuse terminal
58 . . . Screw
71 . . . Vehicle-mountable junction box
72 . . . Lower case
73 . . . Upper case
72a, 73a . . . Housing part

1. A circuit member for a vehicle-mountable junction box, which is to be accommodated in the vehicle-mountable junction box, wherein:
the circuit member is a metal core board including a metal core plate as a core;
the core plate includes a separated part which is separated from a main part by a separating groove filled with an insulating material; and
electronic components are mounted on both of a part including the main part and a part including the separated part.

2. A circuit member according to claim 1, wherein the electronic components mounted on the part including the main part and the electronic components mounted on the part including the separated part are distinguished from each other based on a heat-resistant temperature or a heat-generating temperature of the electronic components.

3. A circuit member for a vehicle-mountable junction box, which is to be accommodated in the vehicle-mountable junction box, wherein:
the circuit member is a busbar wiring body including busbars;
the busbar wiring body includes an insulating plate and the busbars for holding the insulating plate from a front surface and a rear surface of the insulating plate;
the insulating plate has a plurality of positioning parts for positioning the busbars; and
the busbars include the plurality of busbars positioned by the positioning parts.

4. A circuit member for a vehicle-mountable junction box according to claim 3, wherein:
the plurality of busbars include joining parts for connecting the busbars on the front surface of the insulating plate and the busbars on the rear surface of the insulating plate to each other when the busbars hold the insulating plate from the front surface and the rear surface of the insulating plate; and
the joining parts have connection structures formed thereon for connecting and thus integrating the joining parts.

5. A circuit unit for a vehicle-mountable junction box, which is to be accommodated in the vehicle-mountable junction box, wherein:
circuit members included in the circuit unit are a metal core board including a metal core plate as a core and a busbar wiring body including busbars;
the core plate of the metal core board includes a separated part which is separated from a main part by a separating groove filled with an insulating material;
the metal core board has a connection hole formed therein which is electrically connected to the core plate; and
the connection hole is connected to busbars of the busbar wiring body.

6. A circuit unit according to claim 5, wherein the busbar wiring body is a circuit member for a vehicle-mountable junction box, which is to be accommodated in the vehicle-mountable junction box, wherein:
the circuit member includes an insulating plate and the busbars for holding the insulating plate from a front surface and a rear surface of the insulating plate;
the insulating plate has a plurality of positioning parts for positioning the busbars; and
the busbars include the plurality of busbars positioned by the positioning parts.

7. A circuit unit for a vehicle-mountable junction box, which is to be accommodated in the vehicle-mountable junction box, wherein:
a connector holder is fixed on a circuit member included in the circuit unit;
a top surface of the connector holder has an engaging hole formed therein;
a fuse holder having a bottom surface having an engaging protrusion, which is to be inserted into, and engaged with, the engaging hole; and
the fuse holder is fixed on the connector holder by mutual engagement of the engaging hole and the engaging protrusion.

8. A circuit unit for a vehicle-mountable junction box according to claim 7, wherein the circuit member is the circuit member for a vehicle-mountable junction box, which is to be accommodated in the vehicle-mountable junction box, wherein:
the circuit member is a metal core board including a metal core plate as a core;
the core plate includes a separated part which is separated from a main part by a separating groove filled with an insulating material; and
electronic components are mounted on both of a part including the main part and a part including the separated part.

9. A circuit unit for a vehicle-mountable junction box according to claim 7, wherein the connector holder is fixed to the circuit member by a screw, and a hole through which the screw is inserted for engagement is the engaging hole.

10. A vehicle-mountable junction box for accommodating a circuit member according to claim 1, wherein a connection part of a connection terminal, to be connected to a fuse or a connector in a casing for accommodating the circuit member, has a housing for surrounding the connection part of the connection terminal, the housing being integrally formed with the connection part.

11. A vehicle-mountable junction box accommodating a circuit member and/or a circuit unit according to claim 1.
